(19) United States
(12) Patent Application Publication
(10) Pub. No.: US 2023/0420591 A1
(43) Pub. Date: Dec. 28, 2023

(54) PHOTOVOLTAIC MODULE

(71) Applicants: ZHEJIANG JINKO SOLAR CO., LTD., Haining (CN); JINKO SOLAR CO., LTD., Jiangxi (CN)

(72) Inventors: Yingying PENG, Haining (CN); Shuya CHEN, Haining (CN); Guohui HAO, Haining (CN)

(21) Appl. No.: 17/873,118

(22) Filed: Jul. 25, 2022

(30) Foreign Application Priority Data
Jun. 23, 2022 (CN) 202210716629.0

(51) Int. Cl. H01L 31/049; H01L 31/02; H01L 31/05; H01L 31/048

(52) U.S. Cl. CPC H01L 31/049; H01L 31/02; H01L 31/0512; H01L 31/0481

(57) ABSTRACT

A photovoltaic module is provided, including a first cover plate, a first adhesive film, a plurality of cells, a second adhesive film, and a second cover plate. Thicknesses of a respective cell, the first and the second adhesive films are in a range of 100 μm to 170 μm, a range of 300 μm to 550 μm, a range of 300 μm to 710 μm, respectively. The thicknesses of the first and second adhesive films satisfy a relationship: 0.0007x²−0.4297x+374.2≤y≤0.0034x²−1.0297x+314.19, where x and y are the thicknesses of the first and the second adhesive films, respectively. The photovoltaic module further includes at least one welding strip. One end of a respective welding strip is disposed on a front surface of one of two adjacent cells, and the other end of the respective welding strip is disposed on a rear surface of the other of the two adjacent cells.

### CROSS-REFERENCE TO RELATED APPLICATION

The present application claims the benefit of priority under the Paris Convention to Chinese Patent Application No. 202210716629.0 filed on Jun. 23, 2022, which is incorporated herein by reference in its entirety.

### TECHNIC FIELD

Embodiments of the present disclosure relate in general to a photovoltaic cell, and more specifically to a photovoltaic module.

### BACKGROUND

Photovoltaic modules, also known as solar panels, generate electricity through photovoltaic effect, which are the core of solar power systems. The photovoltaic module is generally composed of a cell, a cover plate, and an adhesive film for encapsulating front and rear surfaces of the cell so as to protect the cell.

However, conventional photovoltaic modules have poor performance. It is found that one of the reasons for the poor performance of the photovoltaic module is that the adhesive film not only has the effect of encapsulating the cell, but also reflects light incident on a surface of the cell so as to re-reflect the light into the cell. Generally, in actual preparation of the photovoltaic module, it is found that thicknesses of adhesive films on both sides of the cell affect reflection capability of the adhesive films, so as to affect light absorption capability of the cell, thus resulting in the poor performance of the photovoltaic module.

### SUMMARY

Some embodiments of the present disclosure provide a photovoltaic module, which is at least conducive to improving performance of the photovoltaic module.

Some embodiments of the present disclosure provide a photovoltaic module including: a first cover plate, a first adhesive film, a plurality of cells, a second adhesive film, and a second cover plate; where a thickness of each respective cell of the plurality of cells is in a range of 100 μm to 170 μm, a thickness of the first adhesive film is in a range of 300 μm to 550 μm, a thickness of the second adhesive film is in a range of 300 μm to 710 μm, and the thickness of the first adhesive film and the thickness of the second adhesive film satisfy the following relationship: 0.0007x²−0.4297x+374.2≤y≤0.0034x²−1.0297x+314.19, where x denotes the thickness of the first adhesive film, and y denotes the thickness of the second adhesive film; the photovoltaic module further including at least one welding strip, where one end of each respective welding strip is disposed on a front surface of one of two respective adjacent cells in the plurality of cells, and another end of the respective welding strip is disposed on a rear surface of the other of the two respective adjacent cells, where a thickness of the each respective welding strip is in a range of 200 μm to 400 μm.

In some embodiments, at least one of a thickness difference between the each respective cell and the first adhesive film and a thickness difference between the each respective cell and the second adhesive film is in a range of 200 μm to 350 μm.

In some embodiments, a material of the first cover plate includes glass, the glass has an embossing structure toward a surface of the each respective cell, the embossing structure is recessed in a direction away from the each respective cell, and a recess depth of the embossing structure is in a range of 30 μm to 50 μm.

In some embodiments, a material of the second cover plate includes a back plate, the first adhesive film is disposed between the first cover plate and the plurality of cells, the second adhesive film is disposed between the second cover plate and the plurality of cells, and the thickness of the second adhesive film is less than or equal to the thickness of the first adhesive film.

In some embodiments, a thickness of the first cover plate is in a range of 2.7 mm to 3.2 mm, and a thickness of the back plate is in a range of 0.2 mm to 0.33 mm.

In some embodiments, the thickness of the first adhesive film is in a range of 330 μm to 510 μm, and the thickness of the second adhesive film is in a range of 310 μm to 500 μm.

In some embodiments, a material of the second cover plate includes glass.

In some embodiments, both a thickness of the first cover plate and a thickness of the second cover plate are in a range of 1.5 mm to 2 mm.

In some embodiments, the thickness of the first adhesive film is in a range of 310 μm to 500 μm, and the thickness of the second adhesive film is in a range of 310 μm to 520 μm.

In some embodiments, one of a thickness difference between the each respective welding strip and the first adhesive film and a thickness difference between the each respective welding strip and the second adhesive film is in a range of 50 μm to 180 μm.

In some embodiments, the first adhesive film includes at least one of a poly olefin elastomer (POE) adhesive film and an ethylene vinyl acetate (EVA) adhesive film, and the second adhesive film includes at least one of the POE adhesive film and the EVA adhesive film.

In some embodiments, the thickness of the first adhesive film is equal to the thickness of the second adhesive film when both the first adhesive film and the second adhesive film include POE adhesive films.

In some embodiments, a thickness of the first cover plate is greater than a thickness of the second cover plate.

In some embodiments, the thickness of the first cover plate is in a range of 1.8 mm to 2 mm, and the thickness of the second cover plate is in a range of 1.5 mm to 1.7 mm.

In some embodiments, a shape of the each respective welding strip is any one of circular, rectangular, trapezoidal and triangular.

In some embodiments, adjacent two cells in the plurality of cells are partially overlapped, and a shape of a portion of the each respective welding strip corresponding to an overlapping portion of the adjacent two cells is flat.

In some embodiments, the plurality of cells are disposed in parallel to each other, and a shape of a portion of the each respective welding strip disposed between two parallel cells in the plurality of cells is flat.

In some embodiments, the thickness of the each respective welding strip is any one of 260 μm, 280 μm, 300 μm, and 315 μm.

In some embodiments, a material of the first cover plate includes glass, a material of the second cover plate includes a back plate, the thickness of the each respective cell is 150 μm, the thickness of the first adhesive film is 445 μm, and the thickness of the second adhesive film is 431 μm.

In some embodiments, both a material of the first cover plate and a material of the second cover plate include glass, the thickness of the each respective cell is 155 μm, the thickness of the first adhesive film is 440 μm, the thickness of the second adhesive film is 468 μm, a thickness of the first cover plate is 1.81 mm, and a thickness of the second cover plate is 1.81 mm.

In some embodiments, both a material of the first cover plate and a material of the second cover plate include glass, the thickness of the each respective cell is 155 μm, the thickness of the first adhesive film is 440 μm, the thickness of the second adhesive film is 468 μm, a thickness of the first cover plate is 1.8 mm, and a thickness of the second cover plate is 1.5 mm.

### BRIEF DESCRIPTION OF THE DRAWINGS

One or more embodiments are described as examples with reference to the corresponding figures in the accompanying drawings, and the examples do not constitute a limitation to the embodiments. The figures in the accompanying drawings do not constitute a proportion limitation unless otherwise stated.

FIG. 1 is a schematic cross-sectional view of a photovoltaic module according to an embodiment of the present disclosure.

FIG. 2 is another schematic cross-sectional view of a photovoltaic module according to an embodiment of the present disclosure.

FIG. 3 is still another schematic cross-sectional view of still another photovoltaic module according to an embodiment of the present disclosure.

### DETAILED DESCRIPTION OF THE EMBODIMENTS

Embodiments of the present disclosure provide a photovoltaic module including a first cover plate, a first adhesive film, a plurality of cells, a second adhesive film, and a second cover plate. A thickness of each respective cell of the plurality of cells is in a range of 100 μm to 170 μm, a thickness of the first adhesive film is in a range of 300 μm to 550 μm, a thickness of the second adhesive film is in a range of 300 μm to 710 μm, and the thickness of the first adhesive film and the thickness of the second adhesive film satisfy the following relationship: 0.0007x²−0.4297x+374.2≤y≤0.0034x²−1.0297x+314.19, where x denotes the thickness of the first adhesive film, and y denotes the thickness of the second adhesive film. In this way, the thickness of the first adhesive film and the thickness of the second adhesive film are adapted to the thickness of each respective cell, respectively, so that the first adhesive film and the second adhesive film have better absorption capability for incident light, utilization and absorption of incident light by the cell are improved, thereby improving photoelectric conversion performance of the photovoltaic module. In addition, each respective welding strip is disposed on the surface of the each respective cell, and the thickness of the each respective welding strip is in a range of 200 μm to 400 μm, so that the thickness of the each respective welding strip is adapted to the thickness of the first adhesive film and the thickness of the second adhesive film. In this way, the first adhesive film or the second adhesive film disposed on the surface of the welding strip has a better absorption capacity for incident light.

Various embodiments of the present disclosure are described in detail below with reference to the accompanying drawings. However, those of ordinary skill in the art should appreciate that many technical details have been proposed in various embodiments of the present disclosure for better understanding of the present disclosure. However, the technical solutions claimed in the present disclosure are able to be realized even without these technical details as well as various changes and modifications based on the following embodiments.

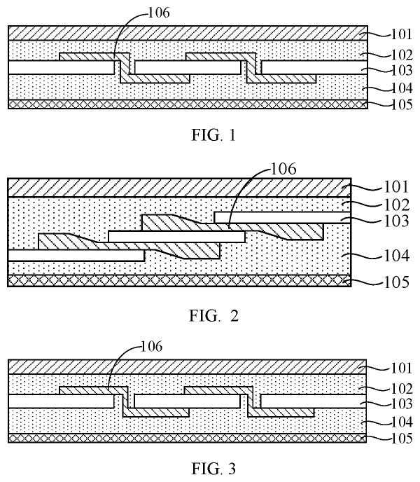

FIG. 1 is a schematic cross-sectional view of a photovoltaic module according to an embodiment of the present disclosure.

Referring to FIG. 1, the photovoltaic module includes a first cover plate 101, a first adhesive film 102, a plurality of cells 103, a second adhesive film 104, and a second cover plate 105. A thickness of each respective cell of the plurality of cells 103 is in a range of 100 μm to 170 μm, a thickness of the first adhesive film 102 is in a range of 300 μm to 550 μm, a thickness of the second adhesive film 103 is in a range of 300 μm to 710 μm, and the thickness of the first adhesive film 102 and the thickness of the second adhesive film 104 satisfy the following relationship: 0.0007x²−0.4297x+374.2≤y≤0.0034x²−1.0297x+314.19, where x denotes the thickness of the first adhesive film 102, and y denotes the thickness of the second adhesive film 104. The photovoltaic module further includes at least one welding strip 106. One end of each respective welding strip 106 is disposed on a front surface of one of two respective adjacent cells 103 in the plurality of cells 103, and another end of the respective welding strip 106 is disposed on a rear surface of the other of the two respective adjacent cells 103. A thickness of the each respective welding strip 106 is in a range of 200 μm to 400 μm.

For each respective cell 103 of the plurality of cells 103, the cell 103 is configured to absorb photons in incident light and generate electron-hole pairs which are separated by a built-in electric field in the cell 103 and generate potential at both ends of a PN junction, thereby converting light energy into electric energy. In some embodiments, one of surfaces of the cell 103 serves as a light receiving surface for absorbing incident light. In other embodiments, both surfaces of the cell 103 serve as light receiving surfaces for absorbing incident light. In some embodiments, the cell 103 may be a crystalline silicon solar cell, such as a single crystal silicon solar cell or a polysilicon solar cell. A plurality of cells 103 are provided, in some embodiments, the plurality of cells 103 may be electrically connected in a form of a whole piece or a plurality of pieces (e.g., a plurality of pieces such as ½ equal pieces, ⅓ equal pieces, ¼ equal pieces, etc.) to form a plurality of cell strings. The plurality of cell strings are electrically connected in series and/or in parallel.

The thickness of the cell 103 is configured to be in a range of 100 μm to 170 μm. Within this range, the thickness of the cell 103 is small, so that an overall weight of the cell 103 is able to be reduced, thereby light weighting the photovoltaic module.

The first adhesive film 102 and the second adhesive film 104 are disposed on opposite surfaces of the cell 103 for encapsulating the cell 103, and the cell 103 may be bonded to the first cover plate 101 and the second cover plate 105. The incident light reaches the surface of the cell 103 via the first adhesive film 102 or the second adhesive film 104 when being irradiated onto the surface of the photovoltaic module. Based on the thickness of the cell 103, the thickness of the first adhesive film 102 is configured to be in a range of 300 μm to 550 μm, and the thickness of the second adhesive film 104 is configured to be in a range of 300 μm to 710 μm. Within this range, the thicknesses of the first adhesive film 102 and the second adhesive film 104 are adapted to the thickness of the cell 103. That is, on the one hand, the thicknesses of the first adhesive film 102 and the second adhesive film 104 are relatively large, so that the first adhesive film 102 and the second adhesive film 104 have a better encapsulation effect on the cell 103, thereby effectively preventing water vapor from entering the cell 103 and causing the failure of the cell 103. On the other hand, within this range, the thicknesses of the first adhesive film 102 and the second adhesive film 104 are not excessively large, so that the first adhesive film 102 and the second adhesive film 104 have a better absorption effect on the incident light, thereby enhancing utilization of the incident light by the cell 103. In addition, the configuration of the thicknesses of the first adhesive film 102 and the second adhesive film 104 within this range makes the amount of prepared first adhesive film 102 and second adhesive film 104 small, which is not only conducive to lightweight of the photovoltaic module, but also reduces the production cost. It should be noted that the thickness of the first adhesive film 102 and the thickness of the second adhesive film 104 respectively refer to the thickness of the first adhesive film 102 on the surface of the cell 103 and the thickness of the second adhesive film 104 on the surface of the cell 103.

In some embodiments, at least one of a thickness difference between the cell 103 and the first adhesive film 102 and a thickness difference between the cell 103 and the second adhesive film 104 is in a range of 200 μm to 350 μm. Within this range, the thickness difference between the first adhesive film 102 and the cell 103 or between the second adhesive film 104 and the cell 103 is relatively large, i.e., the thicknesses of the first adhesive film 102 and the second adhesive film 104 disposed on the surface of the cell 103 are relatively large. On the one hand, the first adhesive film 102 and the second adhesive film 104 are able to seal the cell 103 better, and water vapor is better prevented from entering the cell 103, thus the first adhesive film 102 and the second adhesive film 104 have a better potential induced degradation (PID) resistance effect. On the other hand, within this range, the thicknesses of the first adhesive film 102 and the second adhesive film 104 disposed on the surface of the cell 103 are not excessively large, so that the first adhesive film 102 and the second adhesive film 104 have a better absorption effect on the incident light, thereby improving the utilization of the incident light by the cell 103.

Specifically, in some embodiments, the thickness difference between the first adhesive film 102 and the cell 103 may be in a range of 200 μm to 350 μm. In some embodiments, the thickness difference between the second adhesive film 104 and the cell 103 may be in a range of 200 μm to 350 μm. In some embodiments, both the thickness difference between the first adhesive film 102 and the cell 103 and the thickness difference between the second adhesive film 104 and the cell 103 may be in a range of 200 μm to 350 μm.

When both opposite surfaces of the cell 103 serve as light receiving surfaces to absorb incident light, partial incident light is reflected by the first adhesive film 102 or the second adhesive film 104 at the time the incident light is irradiated onto any one of the first adhesive film 102 or the second adhesive film 104, and the reflected incident light is reflected to the other of the first adhesive film 102 or the second adhesive film 104 by a bottom surface, or diffracted to the other of the first adhesive film 102 or the second adhesive film 104 through surrounding environment, thereby being re-absorbed and utilized by the other of the first adhesive film 102 or the second adhesive film 104. The thicknesses of the first adhesive film 102 and the second adhesive film 104 have a great effect on the absorption rate of the incident light. For example, the larger the thicknesses of the first adhesive film 102 and the second adhesive film 104, the smaller the absorption rate of the incident light by the first adhesive film 102 and the second adhesive film 104.

Based on the above analysis and the thicknesses of the first adhesive film 102, the second adhesive film 104 and the cell 103, the thickness of the first adhesive film 102 and the thickness of the second adhesive film 104 is configured to satisfy the following relationship: 0.0007x²−0.4297x+374.2≤y≤0.0034x²−1.0297x+314.19, where x denotes the thickness of the first adhesive film 102, and y denotes the thickness of the second adhesive film 104. When the first adhesive film 102 and the second adhesive film 104 satisfy the relationship, the thickness of the first adhesive film 102 is adapted to the thickness of the second adhesive film 104, and the thickness of the first adhesive film 102 and the thickness of the second adhesive film 104 are adapted to the thickness of the cell 103, respectively, so that the absorption rate of the other of the first adhesive film 102 or the second adhesive film 104 to the reflected incident light is relatively large when the incident light irradiated onto the first adhesive film 102 or the second adhesive film 104 is reflected to the other of the first adhesive film 102 or the second adhesive film 104, thereby improving the absorption and utilization of the incident light by the photovoltaic module. For example, when the incident light is irradiated onto the surface of the first adhesive film 102, partial incident light is reflected by the bottom surface to the surface of the second adhesive film 104 or is diffracted by the surrounding environment to the surface of the second adhesive film 104, so that the partial incident light is able to be re-absorbed and utilized by the second adhesive film 104.

In some embodiments, the first adhesive film 102 includes at least one of a poly olefin elastomer (POE) adhesive film or an ethylene vinyl acetate (EVA) adhesive film, and the second adhesive film 104 includes at least one of the POE adhesive film or the EVA adhesive film. The POE adhesive film has excellent moisture barrier capability and ion barrier capability and does not produce acid in an aging process, thereby having excellent anti-aging performance and anti-PID effect. The EVA adhesive film makes the incident light in a short-wave band pass through more smoothly, thereby improving the absorption and utilization of the incident light by the cell 103. In some embodiments, both the first adhesive film 102 and the second adhesive film 104 may be POE adhesive films. In some embodiments, both the first adhesive film 102 and the second adhesive film 104 may be EVA adhesive films. In some embodiments, both the first adhesive film 102 and the second adhesive film 104 may include a material of both POE and EVA. For example, both the first adhesive film 102 and the second adhesive film 104 are composite adhesive films, and the composite adhesive film is composed of the POE adhesive film and the EVA adhesive film.

In some embodiments, when both the first adhesive film 102 and the second adhesive film 104 are POE adhesive films, the thickness of the first adhesive film 102 is equal to the thickness of the second adhesive film 104. The thickness of the first adhesive film 102 is the same as the thickness of the second adhesive film 104, so that the first adhesive film 102 and the second adhesive film 104 have the same water vapor barrier capability and ion barrier capability to the two opposite surfaces of the cell 103, thereby having a better encapsulation effect on the entire structure of the cell 103 and maintaining better performance of the cell 103.

The at least one welding strip 106 is further provided. Specifically, in some embodiments, for each respective welding strip 106 of the at least one welding strip 106, the welding strip 106 is disposed on surfaces of grid lines on the cell 103 and connects two adjacent cells 103 so that the two adjacent cells 103 are electrically connected. The welding strip 106 is coated with the first adhesive film 102 or the second adhesive film 104 so that the first adhesive film 102 and the second adhesive film 104 are able to firmly bond the welding strip 106 to the surface of the cell 103. The thickness of the welding strip 106 is configured to be in a range of 200 μm to 400 μm based on the thicknesses of the first adhesive film 102 and the second adhesive film 104, so that the thickness of the welding strip 106 is adapted to the thicknesses of the first adhesive film 102 and the second adhesive film 104, so that the first adhesive film 102 or the second adhesive film 104 disposed on the surface of the welding strip 106 has a better absorption capacity for the incident light, thereby improving performance of the whole photovoltaic module.

Referring to FIG. 1, in some embodiments, the plurality of cells 103 in the photovoltaic module are spaced apart and disposed in parallel. FIG. 1 shows an example of the plurality of cells 103 being disposed in parallel along a horizontal line, and in some embodiments, the plurality of cells 103 may also be disposed in parallel along a vertical line. The welding strip 106 forms an electrical connection between the two adjacent cells 103 by connecting opposite two surfaces of the two adjacent cells 103 respectively (i.e., one end of the welding strip 106 is connected to a front surface of one of the two adjacent cells 103, and another end of the welding strip 106 is connected to a rear surface of the other of the two adjacent cells 103). A shape of the welding strip 106 may be any of circular, rectangular, trapezoidal, or triangular. The welding strip 106 having the above shape has a large thickness, which improves current transmission performance of the welding strip 106.

Referring to FIG. 2, in some embodiments, the plurality of cells 103 in the photovoltaic module are spaced apart, and adjacent two cells 103 are partially overlapped such that the spacing between the two cells 103 is relatively close. Based on this, the shape of the welding strip 106 may be flat, and the flat-shaped welding strip 106 has good bending performance, which is conducive to a lamination process of the photovoltaic module and makes the lamination process easier. In addition, the welding strip 106 is configured to be flat so that the thickness of the welding strip 106 is small. In this way, when the first cover plate 101, the first adhesive film 102, the plurality of cells 103, the second adhesive film 104, and the second cover plate 105 are laminated to form the photovoltaic module, the thickness of the formed photovoltaic module is small, which is conducive to miniaturization of the photovoltaic module. Specifically, in some embodiments, only the shape of the welding strip 106 corresponding to the overlapping portion of the two cells 103 may be flat, and the shape of the welding strip 106 corresponding to unoverlapping portions of the two cells 103 may be any one of circular, rectangular, trapezoidal or triangular. In some embodiments, the shape of the whole welding strip 106 may be configured to be flat.

Referring to FIG. 3, it should be understood that in some embodiments, when the plurality of cells 103 in the photovoltaic module are spaced apart and the plurality of cells 103 are disposed in parallel along a horizontal line, the shape of the welding strip 106 between two adjacent cells 103 may also be configured to be flat. Specifically, in some embodiments, the thickness of the flat-shaped welding strip 106 may be in a range of 100 μm to 150 μm.

In some embodiments, the thickness difference between the first adhesive film 102 and the welding strip 106 or the thickness difference between the second adhesive film 104 and the welding strip 106 is in a range of 50 μm to 180 μm. It should be understood that the thickness difference herein refers to the thickness difference between the welding strip 106 disposed on the surface of the cell 103 and the first adhesive film 102 or the thickness difference between the welding strip 106 disposed on the surface of the cell 103 and the second adhesive film 104. Within this range, the thickness of the first adhesive film 102 or the second adhesive film 104 disposed on the surface of the welding strip 106 is large, so that the first adhesive film 102 or the second adhesive film 104 has a better protective effect on the welding strip 106, and the bonding effect of the first adhesive film 102 or the second adhesive film 104 on the welding strip 106 is better, so that the welding strip 106 is able to be firmly bonded to the surface of the cell 103. In addition, a compression space is able to be provided for the lamination process of the photovoltaic module to prevent damage to the first cover plate or the second cover plate. Within this range, the thickness of the first adhesive film 102 or the second adhesive film 104 disposed on the surface of the welding strip 106 is not excessively large, so that the overall thickness of the first adhesive film 102 and the second adhesive film 104 is small, which is conducive to the preparation of a lightweight photovoltaic module. Specifically, in some embodiments, the thickness of the welding strip 106 may be 260 μm, 280 μm, 300 μm, 315 μm, etc.

The first cover plate 101 and the second cover plate 105 are respectively disposed at opposite sides of the cell 103. The first cover plate 101 may cover the surface of the first adhesive film 102, and the second cover plate 105 may cover the surface of the second adhesive film 104. In some embodiments, the first cover plate 101 may be disposed at a front side of the cell 103, and the second cover plate 105 may be disposed at a rear side of the cell 103. In some embodiments, the first cover 101 may also be disposed at the rear side of the cell 103, and the second cover 105 may also be disposed at the front side of the cell 103. The first cover plate 101 and the second cover plate 105 have good insulation, water resistance, and aging resistance. Therefore, the first cover plate 101 and the second cover plate 105 are disposed at opposite sides of the cell 103 so as to protect and support the cell 103.

With continued reference to FIG. 2, in some embodiments, a material of the first cover plate 101 includes glass, the glass has an embossing structure toward the surface of the cell 103, the embossing structure is recessed in a direction away from the cell 103, and a recess depth of the embossing structure is in a range of 30 μm to 50 μm. Since the glass has good light transmittance, the first cover plate 101 is configured to include glass, so that the absorption effect of the photovoltaic module on the incident light is improved. The embossing structure is disposed on the glass surface, so that the glass surface is a convex surface. In this way, when the incident light incident on the surface of the cell 103 is reflected by the surface of the cell 103, the reflected incident light is diffusely reflected on the embossing structure of the glass surface, so that the reflected incident light is reflected again to the surface of the cell 103 by the embossing structure of the glass surface, so as to enlarge an optical gain of the photovoltaic module, thereby increasing generated power of the photovoltaic module.

The recess depth of the embossing structure is configured to be in a range of 30 μm to 50 μm, which may be, for example, 50 μm. Within this range, the embossing structure has a large degree of concavity, so that the embossing structure has a large degree of roughness, resulting in a good diffuse reflection effect, thereby improving the absorption and utilization of the incident light.

In some embodiments, when the first cover plate 101 includes glass, a material of the second cover plate 105 includes a back plate, the first adhesive film 102 is disposed between the first cover plate 101 and the cell 103, the second adhesive film 104 is disposed between the second cover plate 105 and the cell 103, and the thickness of the second adhesive film 104 is less than or equal to the thickness of the first adhesive film 102. That is, the photovoltaic module is a single glass module. Specifically, in some embodiments, the back plate may be any of a TPC back plate, a PPC back plate, or a CPC back plate. Since the thickness of the glass is larger than the thickness of the back plate, the thickness of the first adhesive film 102 is configured to be larger than the thickness of the second adhesive film 104, thereby prevent the first adhesive film 102 from being damaged due to excessive hardness of the glass during the lamination process.

Since a property of the back plate is different from a property of the glass, in some embodiments, the thickness of the first adhesive film 102 is preferably in a range of 330 μm to 510 μm and the thickness of the second adhesive film 104 is preferably in a range of 310 μm to 500 μm. Within this range, the thickness of the first adhesive film 102 is adapted to the thickness of the glass, and the thickness of the second adhesive film 104 is adapted to the thickness of the back plate, which is conducive to the lamination process. Furthermore, within this range, the thicknesses of the first adhesive film 102 and the second adhesive film 104 are relatively small, which is conducive to the preparation of the lightweight photovoltaic module. In addition, since the thicknesses of the first adhesive film 102 and the second adhesive film 104 are small, absorption of the incident light is further enhanced. Specifically, when the thickness of the first adhesive film 102 is 330 μm, based on the relationship between the first adhesive film 102 and the second adhesive film 104, the thickness of the second adhesive film 104 may be configured to be in a range of 308 μm to 350 μm, and when the thickness of the first adhesive film 102 is 510 μm, the thickness of the second adhesive film 104 may be configured to be in a range of 335 μm to 500 μm. The thicknesses of the first adhesive film 102 and the second adhesive film 104 are configured to satisfy the relationship such that the transmission capability of the first adhesive film 102 to the incident light is adapted to the transmission capability of the second adhesive film 104 to the incident light. In this way, when the incident light is reflected by any one of the first adhesive film 102 and the second adhesive film 104 to the other of the first adhesive film 102 and the second adhesive film 104, the other of the first adhesive film 102 and the second adhesive film 104 is able to transmit most of the reflected incident light again until it is absorbed and utilized by the cell 103, thereby improving the utilization of the incident light by the photovoltaic module.

The incident light first passes through the first cover plate 101 and the second cover plate 105, and then is incident on the first adhesive film 102 and the second adhesive film 104, the incident light reflected by the first adhesive film 102 and the second adhesive film 104 is irradiated on inner surfaces of the first cover plate 101 and the second cover plate 105, and the inner surfaces of the first cover plate 101 and the second cover plate 105 re-reflect the reflected incident light to the surface of the cell 103, thus the adaption of the thickness of the first adhesive film 102 to the thickness of the first cover plate 101 and the adaption of the thickness of the second adhesive film 104 to the thickness of the second cover plate 105 have a large influence on the absorption of the incident light.

Therefore, based on the thickness of the first adhesive film 102 and the thickness of the second adhesive film 104 and properties of the material of the first cover plate 101 and the material of the second cover plate 105, the thickness of the first cover plate 101 may be configured to be in a range of 2.7 mm to 3.2 mm and the thickness of the second cover plate 105 may be configured to be in a range of 0.2 mm to 0.33 mm. In this way, the thickness of the first cover plate 101 is adapted to the thickness of the first adhesive film 102 and the thickness of the second cover plate 105 is adapted to the thickness of the second adhesive film 104, which not only improves a success rate of the lamination process so that the prepared photovoltaic module has better performance, but also makes the absorption capability of the first cover plate 101 for the incident light be adapted to the absorption capability of the first adhesive film 102 for the incident light and makes the absorption capability of the second cover plate 105 for the incident light be adapted to the absorption capability of the second adhesive film 104 for the incident light, thereby improving the absorption and utilization of the incident light by the photovoltaic module.

It should be understood that, in the photovoltaic module provided in the embodiments of the present disclosure, the thicknesses of the first adhesive film 102 and the second adhesive film 104 are configured based on the thickness of the cell 103, and the thicknesses of the first cover plate 101 and the second cover plate 105 are configured based on the thicknesses of the first adhesive film 102 and the second adhesive film 104, i.e., the thickness of the cell 103, the thicknesses of the first cover plate 101 and the second cover plate 105, and the thicknesses of the first adhesive film 102 and the second adhesive film 104 are adapted to each other, so that the absorption and utilization of the incident light by the photovoltaic module is improved, thereby improving the photoelectric conversion performance of the photovoltaic module.

Specifically, when the first cover plate 101 includes the glass and the second cover plate 105 includes the back plate, in some embodiments, the thickness of the cell 103 is 130 μm, the thickness of the first adhesive film 102 is 330 μm, the thickness of the second adhesive film 104 is 308 μm, the thickness of the first cover plate 101 is 2.7 mm, and the thickness of the second cover plate 105 is 0.2 mm. Based on the thicknesses of the first adhesive film 102 and the second adhesive film 104, the thickness of the welding strip 106 on the cell 103 may be 260 μm, and the thickness of the welding strip 106 between two adjacent cells 103 may be 100 μm.

In some embodiments, the thickness of the cell 103 is 150 μm, the thickness of the first adhesive film 102 is 445 μm, the thickness of the second adhesive film 104 is 431 μm, the thickness of the first cover plate 101 is 2.95 mm, and the thickness of the second cover plate 105 is 0.265 mm. Based on the thicknesses of the first adhesive film 102 and the second adhesive film 104, the thickness of the welding strip 106 on the cell 103 may be 280 μm, and the thickness of the welding strip 106 between two adjacent cells 103 may be 125 μm.

In some embodiments, the thickness of the cell 103 is 155 μm, the thickness of the first adhesive film 102 is 461 μm, the thickness of the second adhesive film 104 is 450 μm, the thickness of the first cover plate 101 is 3 mm, and the thickness of the second cover plate 105 is 0.28 mm. Based on the thicknesses of the first adhesive film 102 and the second adhesive film 104, the thickness of the welding strip 106 on the cell 103 may be 300 μm, and the thickness of the welding strip 106 between two adjacent cells 103 may be 135 μm.

In some embodiments, the thickness of the cell 103 is 167 μm, the thickness of the first adhesive film 102 is 510 μm, the thickness of the second adhesive film 104 is 385 μm, the thickness of the first cover plate 101 is 3.2 mm, and the thickness of the second cover plate 105 is in a range of 0.3 mm to 0.33 mm. Specifically, in some embodiments, the second cover 105 may be any one of the TPC back plate, the PPC back plate, or the CPC back plate. When the second cover plate 105 is the TPC back plate, the thickness of the second cover plate 105 may be 0.32 mm. When the second cover plate 105 is the PPC back plate, the thickness of the second cover plate 105 may be 0.315 mm. When the second cover plate 105 is the CPC back plate, the thickness of the second cover plate 105 may be 0.305 mm. Based on the thicknesses of the first adhesive film 102 and the second adhesive film 104, the thickness of the welding strip 106 on the cell 103 may be 315 μm, and the thickness of the welding strip 106 between two adjacent cells 103 may be 150 μm.

In some embodiments, when the first cover plate 101 includes the glass, the material of the second cover plate 105 may also include glass. In other words, the photovoltaic module is a double-glass module, and the structure of the double-glass module is symmetrical because both sides of the cell 103 of the double-glass module are provided with glass, so that both sides of the cell 103 have the same weight, which effectively improves mechanical strength, thereby better protecting the cell 103.

Based on the configuration of the double-glass module, in some embodiments, the thickness of the first adhesive film 102 is in a range of 310 μm to 500 μm and the thickness of the second adhesive film 104 is in a range of 310 μm to 520 μm. Within this range, the adaption of the first adhesive film 102 to the glass and the adaption of the second adhesive film 104 to the glass are better, i.e., the first adhesive film 102 and the second adhesive film 104 are able to be relatively thin, and the first adhesive film 102 or the second adhesive film 104 is able to be prevented from being damaged due to the large hardness of the glass during the lamination process.

Based on the thickness of the first adhesive film 102 and the thickness of the second adhesive film 104 and properties of the material of the first cover plate 101 and the material of the second cover plate 105, the thickness of the first cover plate 101 and the thickness of the second cover plate 105 may be configured to be in a range of 1.5 mm to 2 mm. That is, the thickness of the first cover plate 101 and the second cover plate 105 may be the same. Since the materials of the first cover plate 101 and the second cover plate 105 are the same, the thicknesses of the first cover plate 101 and the second cover plate 105 are configured to be the same so that weights of the first cover plate 101 and the second cover plate 105 are similar or the same, and weights at the two sides of the cell 103 are similar, which is conducive to maintaining the balance of the photovoltaic module, thereby improving of the mechanical strength and mounting stability of the photovoltaic module.

In some embodiments, when both the first cover plate 101 and the second cover plate 105 include the glass, the thickness of the cell 103 is 130 μm, the thickness of the first adhesive film 102 is 310 μm, the thickness of the second adhesive film 104 is 310 μm, the thickness of the first cover plate 101 is 1.5 mm, and the thickness of the second cover plate 105 is 1.5 mm. Based on the thicknesses of the first adhesive film 102 and the second adhesive film 104, the thickness of the welding strip 106 on the cell 103 may be 260 μm, and the thickness of the welding strip 106 between two adjacent cells 103 may be 100 μm.

In some embodiments, the thickness of the cell 103 is 150 μm, the thickness of the first adhesive film 102 is 415 μm, the thickness of the second adhesive film 104 is 396 μm, the thickness of the first cover plate 101 is 1.75 mm, and the thickness of the second cover plate 105 is 1.75 mm. Based on the thicknesses of the first adhesive film 102 and the second adhesive film 104, the thickness of the welding strip 106 on the cell 103 may be 290 μm, and the thickness of the welding strip 106 between two adjacent cells 103 may be 125 μm.

In some embodiments, the thickness of the cell 103 is 155 μm, the thickness of the first adhesive film 102 is 440 μm, the thickness of the second adhesive film 104 is 468 μm, the thickness of the first cover plate 101 is 1.81 mm, and the thickness of the second cover plate 105 is 1.81 mm. Based on the thicknesses of the first adhesive film 102 and the second adhesive film 104, the thickness of the welding strip 106 on the cell 103 may be 300 μm, and the thickness of the welding strip 106 between two adjacent cells 103 may be 131 μm.

In some embodiments, the thickness of the cell 103 is 167 μm, the thickness of the first adhesive film 102 is 500 μm, the thickness of the second adhesive film 104 is 520 μm, the thickness of the first cover plate 101 is 2 mm, and the thickness of the second cover plate 105 is 2 mm. Based on the thicknesses of the first adhesive film 102 and the second adhesive film 104, the thickness of the welding strip 106 on the cell 103 may be 315 μm, and the thickness of the welding strip 106 between two adjacent cells 103 may be 150 μm.

In some embodiments, when both the first cover plate 101 and the second cover plate 105 include the glass, the thickness of the first cover plate 101 and the thickness of the second cover plate 105 may be different. For example, the thickness of the first cover plate 101 is greater than the thickness of the second cover plate 105. Specifically, the thickness of the first cover plate 101 may be in a range of 1.8 mm to 2 mm, and the thickness of the second cover plate 105 may be in a range of 1.5 mm to 1.7 mm.

Specifically, in some embodiments, the thickness of the cell 103 is 155 μm, the thickness of the first adhesive film 102 is 440 μm, the thickness of the second adhesive film 104 is 468 μm, the thickness of the first cover plate 101 is 1.8 mm, and the thickness of the second cover plate 105 is 1.5 mm.

In some embodiments, the thickness of the cell 103 is 167 μm, the thickness of the first adhesive film 102 is 500 μm, the thickness of the second adhesive film 104 is 500 μm, the thickness of the first cover plate 101 is 2 mm, and the thickness of the second cover plate 105 is 1.7 mm.

In the combination of the above different embodiments, the thickness of the first adhesive film 102 and the thickness of the second adhesive film 104 are configured based on the thickness of the cell 103, and the thickness of the first adhesive film 102 and the thickness of the second adhesive film 104 satisfy the following relationship: 0.0007x²−0.4297x+374.2≤y≤0.0034x²−1.0297x+314.19, so that the thicknesses of the first adhesive film 102 and the second adhesive film 104 are adapted to the thickness of the cell 103, and the thickness of the first adhesive film 102 is adapted to the thickness of the second adhesive film 104, so that optical properties of the first adhesive film 102 and the second adhesive film 104 are adapted to each other, and the incident light is further able to be transmitted through the first adhesive film 102 and the second adhesive film 104 and irradiated onto the surface of the cell 103. Furthermore, the thickness of the first cover plate 101, the thickness of the second cover plate 105 and the thickness of the welding strip 106 are configured based on the thicknesses of the first adhesive film 102 and the second adhesive film 104, and in the photovoltaic module obtained therefrom, the thickness of the cell 103, the thicknesses of the first cover plate 101 and the second cover plate 105, and the thicknesses of the first adhesive film 102 and the second adhesive film 104 are all adapted to each other, so that the photovoltaic module has a high absorption and utilization rate for the incident light, and the photoelectric conversion performance of the photovoltaic module is improved.

In the photovoltaic module provided in the above embodiments, under the condition that the thickness of the cell 103 is in a range of 100 μm to 170 μm, the thickness of the first adhesive film 102 is in a range of 300 μm to 550 μm, and the thickness of the second adhesive film 104 is in a range of 300 μm to 710 μm, the thickness of the first adhesive film 102 and the thickness of the second adhesive film 104 satisfy the following relationship: 0.0007x²−0.4297x+374.2≤y≤0.0034x²−1.0297x+314.19, where x denotes the thickness of the first adhesive film 102 and y denotes the thickness of the second adhesive film 104. In this way, the thickness of the first adhesive film 102 and the thickness of the second adhesive film 104 are adapted to the cell 103, respectively, so that the first adhesive film 102 and the second adhesive film 104 have stronger absorption capability for the incident light, and the absorption and utilization of the incident light by the cell 103 is improved, thereby improving the photoelectric conversion performance of the photovoltaic module. Furthermore, the thickness of the welding strip 106 is configured to be in a range of 200 μm to 400 μm so that the thickness of the welding strip 106 is adapted to the thicknesses of the first adhesive film 102 and the second adhesive film 104, thus the first adhesive film 102 and the second adhesive film 104 disposed on the surface of the welding strip 106 have better absorption capacities for the incident light.

The embodiments of the present disclosure described above are not intended to limit the claims. Any one of those skilled in the art may make several possible changes and modifications without departing from the concept of the present disclosure. Therefore, the protection scope of the present disclosure shall be subject to the scope defined in the claims of the present disclosure.

Those of ordinary skill in the art should appreciate that the embodiments described above are specific embodiments of the present disclosure, and in practical application, various changes may be made thereto in form and detail without departing from the spirit and scope of the present disclosure. Any one of those skilled in the art may make their own changes and modifications without departing from the spirit and scope of the present disclosure. Therefore, the protection scope of the present disclosure shall be subject to the scope defined in the claims.

What is claimed is:

1. A photovoltaic module, comprising:
a first cover plate, a first adhesive film, a plurality of cells, a second adhesive film, and a second cover plate;
wherein a thickness of each respective cell of the plurality of cells is in a range of 100 μm to 170 μm, a thickness of the first adhesive film is in a range of 300 μm to 550 μm, a thickness of the second adhesive film is in a range of 300 μm to 710 μm, and the thickness of the first adhesive film and the thickness of the second adhesive film satisfy the following relationship: 0.0007x²−0.4297x+374.2≤y≤0.0034x²−1.0297x+314.19, wherein x denotes the thickness of the first adhesive film, and y denotes the thickness of the second adhesive film;
the photovoltaic module further comprising at least one welding strip, wherein one end of each respective welding strip is disposed on a front surface of one of two respective adjacent cells in the plurality of cells, and another end of the respective welding strip is disposed on a rear surface of the other of the two respective adjacent cells, wherein a thickness of the each respective welding strip is in a range of 200 μm to 400 μm.

2. The photovoltaic module according to claim 1, wherein at least one of a thickness difference between the each respective cell and the first adhesive film and a thickness difference between the each respective cell and the second adhesive film is in a range of 200 μm to 350 μm.

3. The photovoltaic module according to claim 1, wherein a material of the first cover plate includes glass, the glass has an embossing structure toward a surface of the each respective cell, the embossing structure is recessed in a direction away from the each respective cell, and a recess depth of the embossing structure is in a range of 30 μm to 50 μm.

4. The photovoltaic module according to claim 3, wherein a material of the second cover plate includes a back plate, the first adhesive film is disposed between the first cover plate and the plurality of cells, the second adhesive film is disposed between the second cover plate and the plurality of cells, and the thickness of the second adhesive film is less than or equal to the thickness of the first adhesive film.

5. The photovoltaic module according to claim 4, wherein a thickness of the first cover plate is in a range of 2.7 mm to 3.2 mm, and a thickness of the back plate is in a range of 0.2 mm to 0.33 mm.

6. The photovoltaic module according to claim 5, wherein the thickness of the first adhesive film is in a range of 330 μm to 510 μm, and the thickness of the second adhesive film is in a range of 310 μm to 500 μm.

7. The photovoltaic module according to claim 3, wherein a material of the second cover plate includes glass.

8. The photovoltaic module according to claim 7, wherein both a thickness of the first cover plate and a thickness of the second cover plate are in a range of 1.5 mm to 2 mm.

9. The photovoltaic module according to claim 8, wherein the thickness of the first adhesive film is in a range of 310 μm to 500 μm, and the thickness of the second adhesive film is in a range of 310 μm to 520 μm.

10. The photovoltaic module according to claim 1, wherein one of a thickness difference between the each respective welding strip and the first adhesive film and a thickness difference between the each respective welding strip and the second adhesive film is in a range of 50 μm to 180 μm.

11. The photovoltaic module according to claim 1, wherein the first adhesive film includes at least one of a poly olefin elastomer (POE) adhesive film and an ethylene vinyl acetate (EVA) adhesive film, and the second adhesive film includes at least one of the POE adhesive film and the EVA adhesive film.

12. The photovoltaic module according to claim 11, wherein the thickness of the first adhesive film is equal to the thickness of the second adhesive film when both the first adhesive film and the second adhesive film include POE adhesive films.

13. The photovoltaic module according to claim 7, wherein a thickness of the first cover plate is greater than a thickness of the second cover plate.

14. The photovoltaic module according to claim 13, wherein the thickness of the first cover plate is in a range of 1.8 mm to 2 mm, and the thickness of the second cover plate is in a range of 1.5 mm to 1.7 mm.

15. The photovoltaic module according to claim 1, wherein a shape of the each respective welding strip is any one of circular, rectangular, trapezoidal and triangular.

16. The photovoltaic module according to claim 1, wherein adjacent two cells in the plurality of cells are partially overlapped, and a shape of a portion of the each respective welding strip corresponding to an overlapping portion of the adjacent two cells is flat.

17. The photovoltaic module according to claim 1, wherein the plurality of cells are disposed in parallel to each other, and a shape of a portion of the each respective welding strip disposed between two parallel cells in the plurality of cells is flat.

18. The photovoltaic module according to claim 1, wherein the thickness of the each respective welding strip is any one of 260 μm, 280 μm, 300 μm, and 315 μm.

19. The photovoltaic module according to claim 1, wherein a material of the first cover plate includes glass, a material of the second cover plate includes a back plate, the thickness of the each respective cell is 150 μm, the thickness of the first adhesive film is 445 μm, and the thickness of the second adhesive film is 431 μm.

20. The photovoltaic module according to claim 1, wherein both a material of the first cover plate and a material of the second cover plate include glass, the thickness of the each respective cell is 155 μm, the thickness of the first adhesive film is 440 μm, the thickness of the second adhesive film is 468 μm, a thickness of the first cover plate is 1.81 mm, and a thickness of the second cover plate is 1.81 mm.
